(19) United States
(12) Patent Application Publication
(10) Pub. No.: US 2006/0200715 A1
(43) Pub. Date: Sep. 7, 2006

(54) Automatically detecting and routing of test signals

(75) Inventors: Daniel Avery, Chandler, AZ (US); Joel Bailey, Chandler, AZ (US)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., Eindhoven (NL)

(21) Appl. No.: 10/548,993

(22) PCT Filed: Feb. 28, 2004
(86) PCT No.: PCT/IB04/00528

§ 371 Date: Sep. 6, 2005

Related U.S. Application Data
(60) Provisional application No. 60/452,095, filed on Mar. 4, 2003.

(51) Int. Cl. G01R 31/28

(52) U.S. Cl. 714/724

(57) ABSTRACT

A circuit testing approach involves configurable switch control for automatically detecting and routing test signals along a plurality of test circuit paths (240, 242, 244). According to an example embodiment of the present invention, a microcontroller (205) is programmed to monitor input nodes (210) using an interrupt routine for automatically detecting test signals (i.e., digital and/or JTAG test signals). Upon the detection of the test signals, the microcontroller controls a controllable switch (220) for routing the test data along one of the test circuit paths. With this approach, manual switching for routing the test signals is not necessary, which has been found to be useful in applications where access to the circuit paths for switching is difficult or impossible.

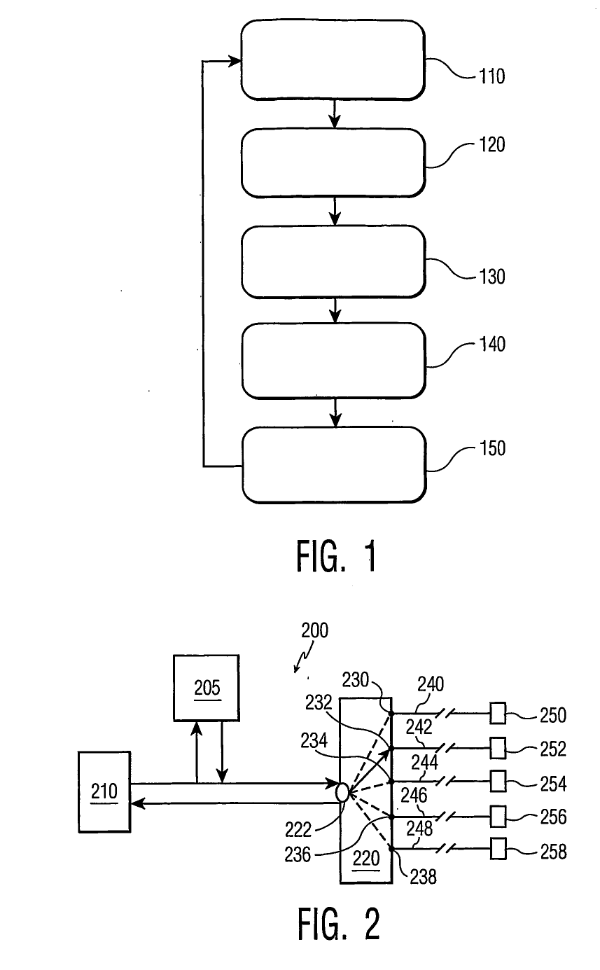

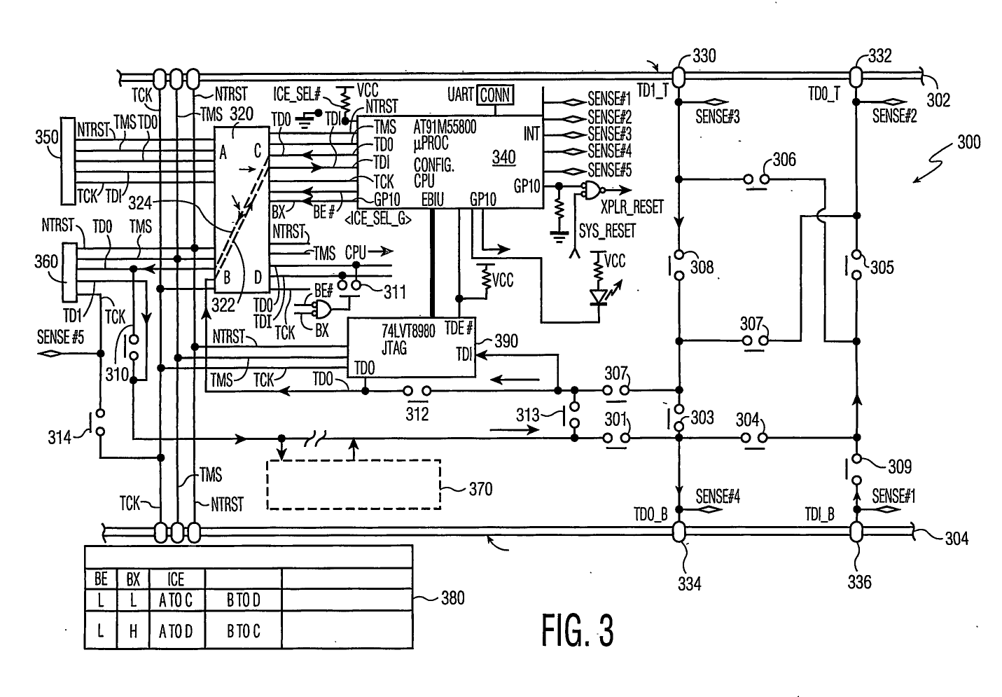

The present invention relates generally to testing integrated circuits (ICs) and, more particularly, to IC test methods and arrangements such as used in connection with IEEE. JTAG (Joint Test Access Group) standards and others involving digital test signals and digital signal protocols.

The electronics industry continues to rely upon advances in semiconductor technology to realize higher-functioning devices in more compact areas. For many applications, realizing higher-functioning devices requires integrating a large number of electronic devices into a single silicon wafer. As the number of electronic devices per given area of the silicon wafer increases, manufacturing and testing processes become more difficult.

A wide variety of techniques have been used in integrated circuit (IC) devices to ensure that, once they are manufactured, they operate fully in compliance with their intended design and implementation specifications. Many of the more complex IC designs include circuits that permit in-circuit testing via the IC access pins. The IEEE 1149.1 JTAG recommendation, for example, provides test circuit architecture for use inside such ICs. This architecture includes a test access port (TAP) controller coupled to the IC pins for providing access to and for controlling various standard features designed into such ICs. Some of these features are internal scan, boundary scan, built-in test and emulation.

For a variety of implementations, different circuit paths are tested using the JTAG recommendation, depending upon the type of test being performed. Mechanical connections (i.e., jumpers) have typically been used to select such a desired circuit path for JTAG-type testing. Setting mechanical connections, however, typically requires access to the connections being set. For example, circuit modules (e.g., permanent and/or reusable blocks and ICs) can be stacked on top of one another, such that in setting jumpers the circuit modules must be pulled apart. If mistakes are made in setting the jumpers, the process of pulling apart the modules and setting the jumpers must be repeated. The implementation of this mechanical connection-setting approach has been challenging. For example, taking apart modules for making connections involves a risk of damaging the connectors, boards and/or other circuitry involved therewith.

In addition, for many chip designs, customized chips are made by describing their functionality using a hardware-description language (HDL), such as Verilog or VHDL. The hardware description is often written to characterize the design in terms of a set of functional macros. The design is computer simulated to ensure that the custom design criteria are satisfied. For highly-complex custom chip designs, the above process can be burdensome and costly. The highly integrated structure of such chips leads to unexpected problems, such as signal timing, noise-coupling and signal-level issues. Consequently, such complex custom chip designs involve extensive validation. This validation is generally performed at different stages using a Verilog or VHDL simulator. Once validated at this level, the Verilog or VHDL HDL code is synthesized, for example, using “Synopsis,” to a netlist that is supplied to an ASIC (Application Specific Integrated Circuit) foundry for prototype fabrication. The ASIC prototype is then tested in silicon. Even after such validation with the Verilog or VHDL simulator, unexpected problems are typical. Overcoming these problems involves more iterations of the above process, with testing and validation at both the simulation and prototype stages. Such repetition significantly increases the design time and cost to such a degree that this practice is often intolerable in today's time-sensitive market.

These and other difficulties present challenges to the design and testing for a variety of applications.

Various aspects of the present invention involve testing approaches for a variety of integrated circuits, such as those including memory circuits and others. The present invention is exemplified in a number of implementations and applications, some of which are summarized below.

According to one example embodiment of the present invention, a controllable switch is operated to couple test signals via a selected circuit path, the switch being controlled in response to the test signals being detected at an input node. With this approach, switching for routing test data is automatically effected, without necessarily involving manual switching approaches, such as those involving the use of jumpers.

In a more particular example embodiment of the present invention, a microcontroller is programmed to automatically monitor test data inputs (TDIs) for testing signals. Upon the detection of a test signal, the microcontroller identifies a particular circuit path to which the test data is to be routed, and controls a switch for routing the test signal between the TDIs and the circuit path. In a more particular implementation, the microcontroller is further programmed to control a switch for routing a response to the test signal to a test data output (TDO).

In another example embodiment of the present invention, an inter-connectable circuit board includes a plurality of circuit paths and controllable switches adapted for routing test data between at least of the circuit paths and a communications node. A microcontroller is programmed for controlling the controllable switches in response to signals monitored at the communications node. In response to detecting a test signal at the communications node, the microcontroller is programmed for identifying a particular one of the circuit paths to which the test signal is to be routed. The microcontroller then controls the controllable switches to couple a signal path between the communications node and the circuit path. With this approach, access to the inter-connectable circuit board, for example, for connecting jumper lines for switching circuits, is not necessary. This approach has also been found useful when the inter-connectable circuit board is connected to another arrangement such that physical access to the inter-connectable circuit board is difficult or not possible.

In another example embodiment, one or more of the circuit paths discussed in the above paragraph include paths for routing test data between the inter-connectable circuit board and another inter-connectable circuit board. The microcontroller detects the presence of the other inter-connectable circuit board in response to the monitored signals and controls the controllable switches for routing data to and from the other inter-connectable circuit board.

The above summary of the present invention is not intended to describe each embodiment or every implementation of the present invention. The above summary of the present invention is not intended to describe each illustrated embodiment or every implementation of the present invention. The figures and detailed description that follow more particularly exemplify these embodiments.

1. A microcomputer arrangement communicatively coupled to JTAG test nodes, the microcomputer arrangement comprising: a controllable switch arrangement communicatively coupled between the JTAG test nodes and at least two JTAG signal paths; and a microcontroller communicatively coupled to the JTAG test nodes and programmed to automatically detect a test signal at one of the JTAG test nodes and, in response to an automatically detected test signal, to control the controllable switch arrangement to route data between at least one of the JTAG test nodes and at least one of the JTAG signal paths.

2. The microcomputer arrangement of claim 1, wherein the microcontroller is programmed for controlling the controllable switch arrangement to route data between the JTAG test nodes and a particular device along one of the JTAG signal paths for performing a JTAG test on the particular device.

3. The microcomputer arrangement of claim 1, wherein the microcontroller is programmed to monitor the JTAG test nodes using an interrupt routine for automatically detecting the test signal.

4. The microcomputer arrangement of claim 3, wherein the microcontroller is programmed to monitor the JTAG test nodes using a plurality of interrupt routines, each of the plurality of interrupt routines being adapted for monitoring one of the JTAG test nodes for detecting a test signal thereon, the microcontroller being adapted for routing the data between the monitored JTAG test node and at least one of the JTAG signal paths in response to the interrupt routine detecting a test signal on the monitored JTAG test node.

5. The microcomputer arrangement of claim 4, wherein each interrupt routine is assigned to a single JTAG test node and wherein the microcontroller is programmed to control the controllable switch to route data between a particular JTAG test node and one of the JTAG signal paths as a function of the assignment of the particular interrupt routine that detects a test signal.

6. The microcomputer arrangement of claim 1, wherein the controllable switch arrangement is adapted to route data along a JTAG signal path from a first JTAG test node to a second JTAG test node in response to the microcontroller.

7. The microcomputer arrangement of claim 1, wherein the controllable switch arrangement is adapted to route data along a JTAG signal path from a first JTAG test node to a device that responds to the data and to route a response of the device to a JTAG test output node.

8. The microcomputer arrangement of claim 7, wherein the device includes at least one of: an FPGA device, an FPGA plug-in board, an expansion board and an external circuit communicatively coupled with the microcontroller.

9. The microcomputer arrangement of claim 1, further comprising an inter-connectable circuit board configured and arranged for connecting to other inter-connectable circuit boards, wherein the controllable switch arrangement and the at least two JTAG signal paths are disposed on the inter-connectable circuit board.

10. The microcomputer arrangement of claim 9, wherein the inter-connectable circuit board is configured and arranged for coupling with another inter-connectable circuit board such that physical access to the controllable switch arrangement is prevented.

11. The microcomputer arrangement of claim 10, wherein the controllable switch arrangement is adapted for routing the data along a JTAG signal path that includes a signal path between the inter-connectable circuit board and the other inter-connectable circuit board.

12. For use in a prototype arrangement of inter-connectable circuit arrangements, each of the inter-connectable circuit arrangements having at least one data-routing switch arrangement, JTAG test nodes and at least two JTAG circuit paths, a circuit controller comprising: a microcontroller coupled to at least one data-routing switch arrangement and to JTAG test nodes on a first one of the inter-connectable circuit arrangements, the microcontroller being programmed to automatically control the data-routing switch arrangement in response to a signal detected from at least one of the JTAG test nodes, the data-routing switch arrangement being controlled for routing JTAG test signals along one of the at least two JTAG circuit paths on the first one of the inter-connectable circuit arrangements.

13. The circuit controller of claim 12, wherein the microcontroller is programmed to control the data-routing switch arrangement for routing JTAG test signals between two of the inter-connectable circuit arrangements.

14. The circuit controller of claim 12, wherein the microcontroller is programmed to perform an interrupt routine for detecting the signal from the at least one of the plurality of test nodes.

15. The circuit controller of claim 12, wherein the microcontroller is disposed on the first one of the inter-connectable circuit arrangements.

16. The circuit controller of claim 12, wherein each of the inter-connectable circuit arrangements includes at least one JTAG input test node and at least one JTAG output test node and wherein the JTAG output test node of the first one of the inter-connectable circuit arrangements is coupled to a JTAG input test node of a second one of the inter-connectable circuit arrangements.

17. The circuit controller of claim 12, wherein the first one of the inter-connectable circuit arrangements includes at least one circuit device and wherein the microcontroller is programmed to control the data-routing switch arrangement to route test data from at least one of the JTAG test nodes to the circuit device.

18. The circuit controller of claim 17, wherein the circuit device includes at least one of: an FPGA device, an FPGA plug-in board, an expansion board and an external circuit communicatively coupled with the circuit controller.

19. The circuit controller of claim 12, wherein the first one of the inter-connectable circuit arrangements is configured and arranged for coupling with another one of the inter-connectable circuit arrangements such that physical access to the data-routing switch arrangement is prevented.

20. The circuit controller of claim 12, wherein the microcontroller is adapted for detecting a signal from a second one of the inter-connectable circuit arrangements and, in response thereto, controlling the data-routing switch arrangement for routing test data between the first one of the inter-connectable circuit arrangements and the second one of the inter-connectable circuit arrangements.

21. A microcomputer arrangement communicatively coupled to JTAG test nodes, the microcomputer arrangement comprising: switching means communicatively coupled between the JTAG test nodes and at least two JTAG signal paths; and controlling means communicatively coupled to the JTAG test nodes and programmed to automatically detect a test signal at one of the JTAG test nodes and, in response to an automatically detected test signal, to control the switching means to route data between at least one of the JTAG test nodes and at least one of the JTAG signal paths.

22. A microcomputer arrangement communicatively coupled to digital signal test nodes, the microcomputer arrangement comprising: a controllable switch arrangement communicatively coupled between the digital signal test nodes and at least two digital signal paths; and a microcontroller communicatively coupled to the digital signal test nodes and programmed to automatically detect a test signal at one of the digital signal test nodes and, in response to an automatically detected test signal, to control the controllable switch arrangement to route data between at least one of the digital signal test nodes and at least one of the digital signal paths.

23. A system for designing a semiconductor device, the system comprising: a deconfigurable and extendible reference-chip development platform that is programmable, and includes a hardware reconfigurable circuit and a plurality of functional block macros, the hardware reconfigurable circuit comprising: a controllable switch arrangement communicatively coupled between the JTAG test nodes and at least two JTAG signal paths; and a microcontroller communicatively coupled to the JTAG test nodes and programmed to automatically detect a test signal at one of the JTAG test nodes and, in response to an automatically detected test signal, to control the controllable switch arrangement to route data between at least one of the JTAG test nodes and at least one of the JTAG signal paths; a collection of functional block macros, at least one of which is obtained from the deconfigurable and extendible reference-chip development platform; an interface circuit configured and arranged to extend the deconfigurable and extendible reference-chip development platform, including a two-way buffer arrangement and logic circuitry adapted to communicatively couple a plurality of external devices with the reference-chip development platform, and therein provide an extended deconfigurable and extendible reference chip development platform that enables co-development and co-validation of hardware and software; a synthesizer adapted to cause said at least one of the functional block macros to be represented as a configuration of the hardware reconfigurable circuit; and wherein the extended deconfigurable and extendible reference-chip development platform is adapted to validate the configuration in the hardware reconfigurable circuit within the extended deconfigurable and extendible reference-chip development platform.
